(19) United States
(12) Patent Application Publication
(10) Pub. No.: US 2009/0321120 A1
(43) Pub. Date: Dec. 31, 2009

(54) PRINTED CIRCUIT BOARD AND ELECTRONIC DEVICE

(75) Inventors: Syuji HIRAMOTO, Kokubunji-shi (JP); Norihiro ISHII, Akishima-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/495,507

(22) Filed: Jun. 30, 2009

(30) Foreign Application Priority Data
Jun. 30, 2008 (JP) 2008-171205

(51) Int. Cl. H05K 1/18

(52) U.S. Cl. 174/260

(57) ABSTRACT

A printed circuit board according to the present invention includes a printed wiring board, first electrodes, second electrodes, third electrodes, solders, and a flip chip. The printed wiring board includes a first surface and a second surface which is opposite the first surface. The first electrodes are respectively formed on the first surface. The second electrodes correspond to and are disposed near each of the first electrodes, and are respectively formed on the first surface. The third electrodes electrically respectively connect the first electrodes and the second electrodes corresponding to each of the first electrodes. The solders are applied so as to respectively cover the first electrodes, the second electrodes corresponding to the first electrodes, and the third electrodes connecting the first electrodes and the second electrodes. The flip chip is electrically connected to each of the first electrodes at a position opposed to the first electrodes.

### CROSS-REFERENCE TO RELATED APPLICATIONS

This application claims the benefit of priority of Japanese Patent Application No. 2008-171205, filed Jun. 30, 2008, the entire contents of which are incorporated herein by reference.

### BACKGROUND

1. Field

The present invention relates to a printed circuit board and an electronic device in which electrodes for implementing a peripheral type flip chip are formed on a printed wiring board.

2. Description of the Related Art

An electrode body for implementing a fine-pitch SoC flip chip is formed by scraping off an insulating film such as a solder resist (a thermosetting epoxy resin film) with a method such as etching to expose a wiring. The exposed electrode body is plated with Ni/Au or Cu-prefluxed as appropriate. On a printed wiring board that is assumed to implement a flip chip (having, for example, a bump diameter of about 170 um, a bump height of about 50 um, a passivation opening of about φ 150 um, and a bump pitch of about 500 um), the portion that is formed with an electrode body of φ 150 um and a solder resist opening of φ 200 um, for example, is an electrode.

As a document of the related art relevant to the present invention, there is Japanese Patent Application Publication No. 8-307050.

It is known that when solder printing is performed on a printed wiring board, if an aspect ratio R defined from a diameter of a metal mask opening(an area of an opening) and a thickness of a metal mask (an area of a side surface of a mask opening) such that R=r/2t (where r is a radius of a metal mask opening and t is a thickness of a metal mask) is less than 0.7, and a solder paste having a grain diameter of about 30 um is used, releasability of a metal mask that has stickiness is significantly decreased. For example, if r is 75 um and t is 100 um, then R will be 0.375, or less than 0.7, causing solder printing to be substantially impossible. Thus it is consequently difficult to perform fine-pitch SoC implementation with a conventional SMT method.

### SUMMARY OF THE INVENTION

Accordingly, an object of the present invention, which was made in view of the above circumstances, is to provide a printed circuit board and an electronic device with which a peripheral type flip chip can be securely implemented.

To solve the above problems, a printed circuit board according to the present invention includes: a printed wiring board including a first surface and a second surface which is opposite the first surface; a plurality of first electrodes respectively formed on the first surface; a plurality of second electrodes corresponding to and disposed near each of the first electrodes, and respectively formed on the first surface; a plurality of third electrodes electrically respectively connecting the first electrodes and the second electrodes corresponding to each of the first electrodes; a plurality of solders applied so as to respectively cover the first electrodes, the second electrodes corresponding to the first electrodes, and the third electrodes connecting the first electrodes and the second electrodes; and a flip chip electrically connected to each of the first electrodes at a position opposed to the first electrodes, and implemented on the first surface.

To solve the above problems, a printed circuit board according to the present invention includes: a printed wiring board including a first surface and a second surface which is opposite the first surface; a plurality of first electrodes respectively formed on the first surface; a plurality of second electrodes corresponding to and disposed near each of the first electrodes, and respectively formed on the first surface; a plurality of solders applied so as to respectively cover the first electrodes and the second electrodes corresponding to the first electrodes; and a flip chip electrically connected to each of the first electrodes at a position opposed to the first electrodes, and implemented on the first surface.

Further, to solve the above problems, an electronic device according to the present invention including a printed circuit board, the printed circuit board includes: a printed wiring board including a first surface and a second surface which is opposite the first surface; a plurality of first electrodes respectively formed on the first surface; a plurality of second electrodes corresponding to and disposed near each of the first electrodes, and respectively formed on the first surface; a plurality of third electrodes electrically respectively connecting the first electrodes and the second electrodes corresponding to each of the first electrodes; a plurality of solders applied so as to respectively cover the first electrodes, the second electrodes corresponding to the first electrodes, and the third electrodes connecting the first electrodes and the second electrodes; and a flip chip electrically connected to each of the first electrodes at a position opposed to the first electrodes, and implemented on the first surface.

In accordance with the printed circuit board and the electronic device according to one aspect of the present invention, a peripheral type flip chip can be securely implemented.

### BRIEF DESCRIPTION OF THE DRAWINGS

FIG. 1 is a schematic view showing an external appearance of a hard drive as an electronic device of the embodiment.

FIG. 2 is a pattern diagram showing a first example of a printed wiring board which constitutes a printed circuit board.

FIG. 3 is a cross-sectional view of the first example of the printed wiring board shown in FIG. 2 as taken along line III-III.

FIG. 4 is a pattern diagram showing a second example of a printed wiring board which constitutes a printed circuit board.

FIG. 5 is a cross-sectional view of the second example of the printed wiring board shown in FIG. 4 as taken along line V-V.

FIG. 6 is a pattern diagram showing a third example of a printed wiring board which constitutes a printed circuit board.

FIG. 7 is a schematic external view showing a state in which solder printing is performed on the printed wiring board shown in FIGS. 2 and 3 using a metal mask.

FIG. 8 is a pattern diagram showing a state of the first example of the printed wiring board shown in FIG. 2 after solder printing.

FIG. 9 is a cross-sectional view of the first example of the printed wiring board shown in FIG. 8 as taken along line IX-IX.

FIG. 10 is a pattern diagram showing a state of the second example of the printed wiring board shown in FIG. 4 after solder printing.

FIG. 11 is a cross-sectional view of the second example of the printed wiring board shown in FIG. 10 as taken along line XI-XI.

FIG. 12 shows a variation of the cross-sectional view shown in FIG. 11.

FIG. 13 is a cross-sectional view showing one example of a printed wiring board that uses a filled via.

### DETAILED DESCRIPTION

An embodiment of a printed wiring board and an electronic device according to one aspect of the present invention will be described with reference to the accompanying drawings.

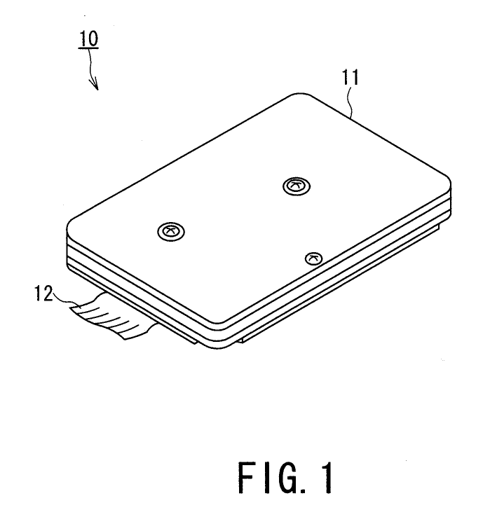

FIG. 1 is a schematic view showing an external appearance of a hard disk drive as an electronic device of the embodiment.

FIG. 1 shows an HDD 10 as an electronic device of the embodiment. The HDD 10 has a chassis 11 which has a substantially rectangular box shape and accommodates various sorts of members described below, and a printed circuit board 12 which is disposed on top of an outer surface of the chassis 11 and implements a peripheral type flip chip. On the printed circuit board 12, a peripheral type flip chip is implemented.

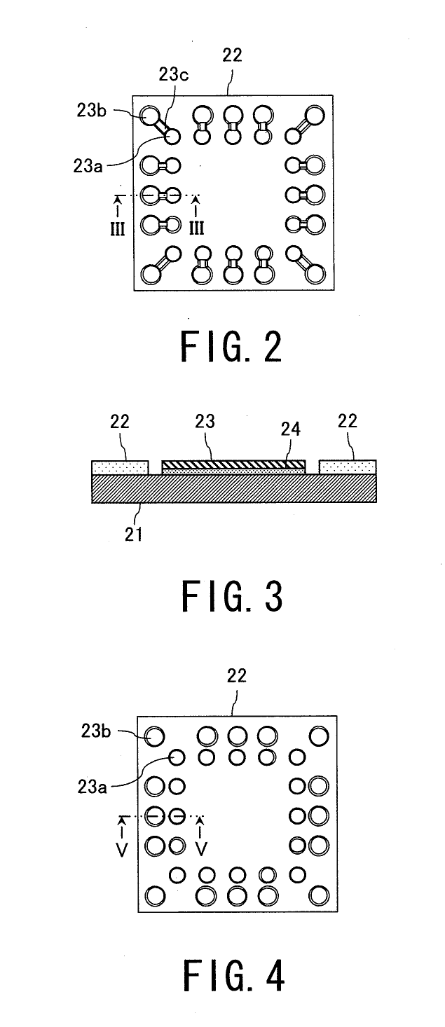

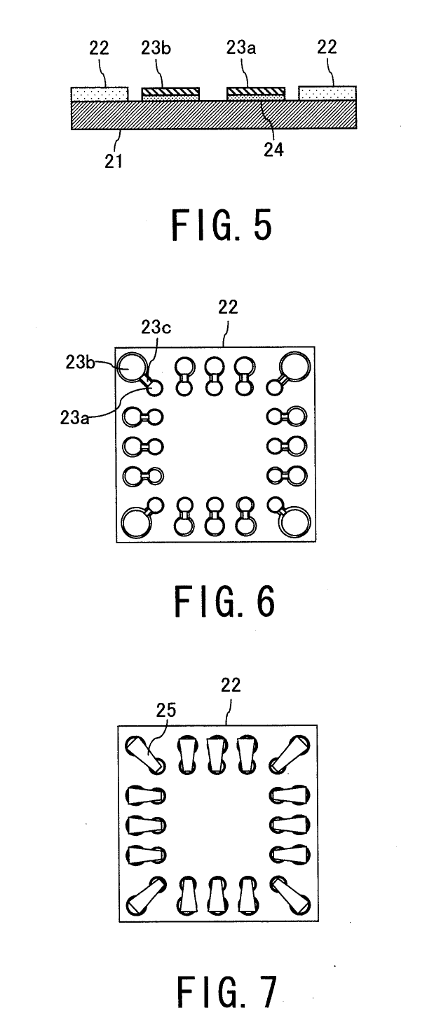

FIG. 2 is a pattern diagram showing a first example of a printed wiring board which constitutes the printed circuit board 12. FIG. 3 is a cross-sectional view of the first example of the printed wiring board shown in FIG. 2 as taken along line III-III. FIG. 4 is a pattern diagram showing a second example of a printed wiring board which constitutes the printed circuit board 12. FIG. 5 is a cross-sectional view of the second example of the printed wiring board shown in FIG. 4 as taken along line V-V. FIG. 6 is a pattern diagram showing a third example of a printed wiring board which constitutes the printed circuit board 12.

As shown in FIGS. 2 and 3, the printed circuit board 12 includes a printed wiring board 21 which has mutually opposite first and second surfaces, and a solder resist 22, electrodes 23, and a copper foil 24 formed on the first surface of the printed wiring board 21. The electrodes 23 are formed on the copper foil 24 of the printed wiring board 21 which constitutes the printed circuit board 12 by removing an outer copper foil after using conventional etching (or a filled via) and disposing the solder resist 22 around the electrodes 23.

The electrodes 23 include a plurality of first electrodes 23a which are used to implement a flip chip, a plurality of second electrodes 23b which are not used to implement a flip chip, which correspond to each of the plurality of first electrodes 23a and which are formed near the first electrodes 23a, such as outward of the first electrodes 23a in a planar direction, and a plurality of third electrodes which are not used to implement a flip chip and which electrically connect the first electrodes 23a and the second electrodes 23b. The first electrodes 23a are formed, for example, in a circular shape having a diameter of 150 [um]. It is desirable that the second electrodes 23b and the third electrodes 23c also have the same circular shape as the first electrodes 23a for the purpose of manufacturing the printed circuit board 12. Note that the method of removing an outer layer copper foil may be chemical etching or a physical method such as grinding.

In the case of the above, By respectively adjusting the surface areas of the second electrode 23b and the third electrode 23c to set a diameter of a metal mask opening so that an aspect ratio R defined from a diameter of a metal mask opening(an area of an opening) and a thickness of a metal mask (an area of a side surface of a mask opening) such that R=r/2t (where r is a radius of a metal mask opening and t is a thickness of a metal mask) is 0.7 or higher, releasability of a metal mask is increased.

The electrodes 23 of the printed circuit board 12 shown in FIGS. 4 and 5 include only the first electrodes 23a and the second electrodes 23b. By adjusting the surface area of the second electrode 23b to set a diameter of a metal mask opening so that an aspect ratio is 0.7 or higher, releasability of a metal mask is increased. On the printed circuit board 12 shown in FIG. 6, some of the second electrodes 23b that correspond to the four corners of a rectangular-shaped flip chip that is to be implemented are formed in a circular shape that is larger than the rest of the second electrodes 23b. In that case, a self-alignment effect is achieved as the second electrodes 23b corresponding to the four corners of the flip chip pull the flip chip in radial directions when solder melts during a reflow process.

FIG. 7 is a schematic view showing a state in which solder printing is performed on the printed wiring board shown in FIGS. 2 and 3 using a metal mask.

Solder printing is performed by using a metal mask that has an opening in a trapezoidal shape so that a solder paste 25 covers the electrode 23 and the solder resist 22 of the printed wiring board 21 shown in FIGS. 2 and 3. Since the total surface area of the first electrode 23a, the second electrode 23b, and the third electrode 23c is increased while the surface area of the first electrode 23a remains the same, the area of the metal mask opening is significantly increased. Therefore, it is possible to perform solder printing for implementing a fine-pitch flip chip with a conventional solder printing method, because an aspect ratio R is significantly increased (to 0.7 or higher).

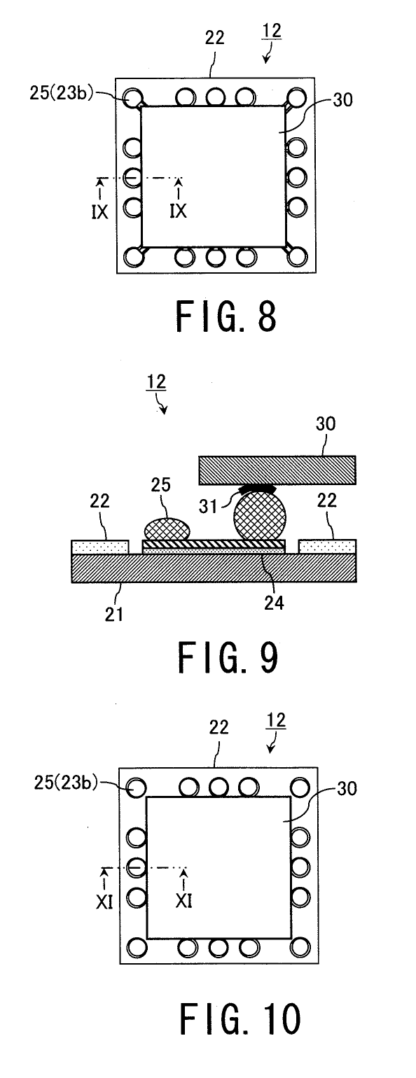

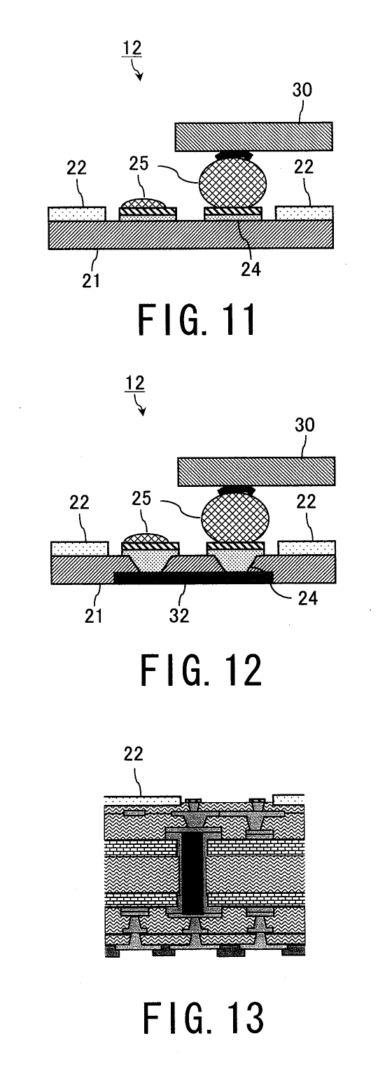

FIG. 8 is a pattern diagram showing a state of the first example of the printed wiring board shown in FIG. 2 after solder printing. FIG. 9 is a cross-sectional view of the first example of the printed wiring board shown in FIG. 8 as taken along line IX-IX. FIG. 10 is a pattern diagram showing the second example of the printed wiring board shown in FIG. 4 after solder printing. FIG. 11 is a cross-sectional view of the second example of the printed wiring board shown in FIG. 10 as taken along line XI-XI. FIG. 12 shows a variation of the cross-sectional view shown in FIG. 10.

As shown in FIGS. 8 and 9, since the solder 25 melts at around a peak temperature and spreads into the second electrode 23b without spreading over the solder resist 22 or the printed wiring board 21 during a reflow process after solder printing, it is applied so as to cover the first electrode 23a, the second electrode 23b corresponding to the first electrode 23a, and the third electrode 23c connecting the first electrode 23a and the second electrode 23b. Therefore, a passivation layer 31 of a flip chip 30 and the printed wiring board 21 are joined by solder on the first electrode 23a with a suitable amount of the solder 25, and an excess amount of the solder 25 moves through the third electrode 23c into the second electrode 23b. In this way, the fine-pitch flip chip 30 is implemented on the first surface of the printed wiring board 21 (where the electrode 23 is formed) and electrically connected to the plurality of first electrodes 23b at a position opposed to the plurality of first electrodes 23b by a conventional SMT method comprising the steps of printing, mounting, and reflowing. Also, the second electrodes 23b can be used for testing an electrical property, facilitating debugging tasks.

Note that if the second electrodes 23b are formed outward of the first electrodes 23a in a planar direction, the second electrodes 23b can be used as testing pads. On the other hand, if some parts are implemented around the outer circumference of the flip chip 30 and the second electrodes 23b cannot be formed outward of the first electrodes 23a in a planar direction, or if the electrodes 23 do not include the third electrodes 23c, as shown in FIGS. 10 and 11, the second electrodes 23b cannot be used as testing pads. However, a conductive member 32 can be disposed on an inner layer of the printed wiring board 21, as shown in FIG. 12.

FIG. 13 is a cross-sectional view showing one example of the printed wiring board 21 that uses a filled via.

As shown in FIG. 13, if a filled via of the printed wiring board 21 is used, an outer copper foil may be removed either partly or completely. If the outer copper foil is removed completely, a solder resist-less structure can be achieved. In that case, stable solder printability can be achieved as well.

The first electrode 23a of the printed wiring board 21 included in the HDD 10 of the embodiment may have a diameter of about 150 [um] as an electrode size that is close to a passivation opening size of the flip chip 30, especially if a filled via is used for an electrode. Also, in the cases of FIG. 11 and FIG. 12, since the electrode 23 has a circular shape, the shape of a solder bump will be generally rotationally symmetric. This makes areas where solder spreads on the passivation layer 31 of the flip chip 30 and on the electrode 23 of the printed wiring board 21 generally equal, allowing strain that occurs in response to thermal stress at the vicinity of the joint interface between the passivation layer 31 of the flip chip 30 and the solder bump to be decreased. Long-term solder joint reliability of the flip chip 30 as a semiconductor component is thus significantly increased. Generally, if an inexpensive printed wiring board 21 such as a through substrate is used, the shape of the electrode 23 shown in FIGS. 2 and 3 is preferable, and if a build-up substrate can be used, the shape of the electrode 23 shown in FIGS. 4 and 5 is preferable.

According to the HDD 10 of the embodiment, by forming the second electrode 23b (and the third electrode 23c) which is used to implement a flip chip in addition to the first electrode 23a which is used to implement a flip chip on the printed wiring board 21 to increase a surface area of the electrode 23, an area of a metal mask opening is increased (or R is increased), allowing a peripheral type flip chip to be securely implemented.

What is claimed is:

1. A printed circuit board comprising:
a printed wiring board comprising a first surface on the printed wiring board and a second surface on the printed wiring board opposite to the first surface;
a plurality of first electrodes on the first surface;
a plurality of second electrodes corresponding to each of the first electrodes on the first surface;
a plurality of third electrodes electrically connecting the first electrodes and the second electrodes corresponding to each of the first electrodes;
a plurality of solders configured to cover the first electrodes, the second electrodes corresponding to the first electrodes, and the third electrodes connected to the first electrodes and the second electrodes; and
a flip chip electrically connected to each of the first electrodes at a position facing the first electrodes, and implemented on the first surface.

2. The printed circuit board of claim 1, wherein a surface area of the second electrodes and a surface area of the third electrodes are adjusted so that an aspect ratio R (an area of a mask opening divided by an area of a side surface of a mask) is 0.7 or higher.

3. The printed circuit board of claim 2, wherein each of the second electrodes are in the same shape as the first electrodes.

4. The printed circuit board of claim 3, wherein each of the second electrodes are outward of the first electrodes in a planar direction.

5. The printed circuit board of claim 3, wherein each of the second electrodes are inward of the first electrodes in a planar direction.

6. The printed circuit board of claim 4, wherein predetermined second electrodes of the second electrodes corresponding to the four corners of the flip chip in a rectangular shape are located such that a surface area of each predetermined second electrodes is larger than a surface area of each of the rest of the second electrodes.

7. The printed circuit board of claim 5, wherein predetermined second electrodes of the second electrodes corresponding to the four corners of the flip chip in a rectangular shape are located such that a surface area of each predetermined second electrodes is larger than a surface area of each of the rest of the second electrodes.

8. A printed circuit board comprising:
a printed wiring board comprising a first surface on the printed wiring board and a second surface on the printed wiring board opposite to the first surface;
a plurality of first electrodes on the first surface;
a plurality of second electrodes corresponding to each of the first electrodes on the first surface;
a plurality of solders configured to cover the first electrodes and the second electrodes corresponding to the first electrodes respectively; and
a flip chip electrically connected to each of the first electrodes at a position facing the first electrodes, and implemented on the first surface.

9. An electronic device comprising a printed circuit board, the printed circuit board comprising:
a printed wiring board comprising a first surface on the printed wiring board and a second surface on the printed wiring board opposite to the first surface;
a plurality of first electrodes on the first surface;
a plurality of second electrodes corresponding to each of the first electrodes on the first surface;
a plurality of third electrodes electrically connecting the first electrodes and the second electrodes corresponding to each of the first electrodes;
a plurality of solders configured to cover the first electrodes, the second electrodes corresponding to the first electrodes, and the third electrodes connected to the first electrodes and the second electrodes; and
a flip chip electrically connected to each of the first electrodes at a position facing the first electrodes, and implemented on the first surface.
